(19) United States
(12) Patent Application Publication
(10) Pub. No.: US 2025/0329561 A1
(43) Pub. Date: Oct. 23, 2025

(54) SEMICONDUCTOR PROCESSING APPARATUS

(71) Applicant: Samsung Electronics Co., Ltd., Suwon-si (KR)

(72) Inventors: Sanghoon HAN, Suwon-si (KR); Hyeseon KWON, Suwon-si (KR); Yunha KIM, Suwon-si (KR); Kwanghyun CHO, Suwon-si (KR)

(73) Assignee: Samsung Electronics Co., Ltd., Suwon-si (KR)

(21) Appl. No.: 19/027,210

(22) Filed: Jan. 17, 2025

(30) Foreign Application Priority Data
Apr. 23, 2024 (KR) 10-2024-0053973

(51) Int. Cl. H01L 21/67; G05B 13/02

(52) U.S. Cl. CPC H01L 21/67248; G05B 13/0265

(57) ABSTRACT

A semiconductor processing apparatus may include a wafer support including a heater; a heater power supply configured to supply heater power to the heater; and a processor configured to receive a setting signal indicating a set temperature of the wafer support, determine the heater power using the setting signal, receive a measurement signal obtained by measuring the temperature of the wafer support, generate an error signal based on the setting signal and the measurement signal, generate a feedforward signal based on the setting signal, generate an iterative learning signal based on the error signal, generate a feedback signal based on the error signal, determine a control signal based on the feedforward, iterative learning, and feedback signals, output the control signal to the heater power supply, and determine the heater power in a sampling period of the measurement signal being within a target range as a final heater power.

### CROSS-REFERENCE TO RELATED APPLICATION

This application claims benefit of priority to Korean Patent Application No. 10-2024-0053973 filed on Apr. 23, 2024 in the Korean Intellectual Property Office, the disclosure of which is incorporated herein by reference in its entirety.

### BACKGROUND

The present inventive concepts relate to semiconductor processing apparatuses.

A semiconductor process, such as deposition, etching or the like, using plasma may be performed in a semiconductor processing apparatus. Before the semiconductor process proceeds, physical quantities used in the semiconductor processing apparatus, such as a temperature of a wafer support, radio frequency (RF) power, gas flow rate, chamber pressure or the like, may be established. Because the physical quantities may affect process results, it may be important that the physical quantities remain stable during the semiconductor process.

The temperature of the wafer support may take considerable time to stabilize, and a change in the temperature of the wafer support may have a significant impact on the process results. Therefore, while the semiconductor process is in progress, it may be important to control the temperature of the wafer support to be quickly stabilized and maintained.

### SUMMARY

Some aspects of the present inventive concepts are to calculate final heater power supplied to a heater by means of iterative learning-based feedforward and feedback controls before proceeding with a semiconductor process, thereby controlling a measured temperature of a wafer support controlled by the final heater power to be maintained within a target range while the semiconductor process is in progress.

According to some aspects of the present inventive concepts, a semiconductor processing apparatus includes a wafer support including a heater; a heater power supply configured to supply heater power to the heater to control a temperature of the wafer support; and a processor configured to receive a setting signal indicating a set temperature of the wafer support, determine the heater power using the setting signal, receive a measurement signal obtained by measuring the temperature of the wafer support, generate an error signal based on the setting signal and the measurement signal, generate a feedforward signal based on the setting signal, generate an iterative learning signal based on the error signal, generate a feedback signal based on the error signal, determine a control signal based on the feedforward signal, the iterative learning signal, and the feedback signal as the heater power, output the control signal to the heater power supply, and determine the heater power in a sampling period as a final heater power, the sampling period based on the measurement signal being maintained within a target range.

According to some aspects of the present inventive concepts, a semiconductor processing apparatus includes a wafer support including a heater; a heater power supply configured to supply heater power to the heater to control a temperature of the wafer support based on a semiconductor process being in progress; and a processor including a feedforward controller, an iterative learning controller and a feedback controller, and the processor being configured to receive a setting signal indicating a set temperature of the wafer support, determine the heater power using the setting signal, receive a measurement signal obtained by measuring the temperature of the wafer support on which disturbance is reflected, generate an error signal based on a difference between the setting signal and the measurement signal, transmit the setting signal to the feedforward controller, control the feedforward controller to output a feedforward signal based on the setting signal, transmit the error signal to the iterative learning controller, control the iterative learning controller to receive the error signal and output an iterative learning signal based on the error signal, and transmit the error signal to the feedback controller, control the feedback controller to receive the error signal and generate a feedback signal based on the error signal, determine a control signal obtained based on the feedforward signal, the iterative learning signal, and the feedback signal as the heater power, output the control signal to the heater power supply, and determine the heater power in a sampling period as a final heater power, the sampling period being based on the measurement signal being maintained within a target range.

According to some aspects of the present inventive concepts, a semiconductor processing apparatus includes a wafer support including a heater; a heater power supply configured to supply heater power to the heater to control a temperature of the wafer support, based on a semiconductor process being in progress; and a processor configured to receive a setting signal indicating a set temperature of the wafer support, determine the heater power using the setting signal, receive a measurement signal obtained by measuring the temperature of the wafer support on which disturbance is reflected, generate an error signal based on a difference between the setting signal and the measurement signal, generate a feedforward signal based on feedforward controlling the setting signal, generate an iterative learning signal based on iterative learning controlling the error signal, generate a feedback signal based on feedback controlling the error signal, determine a control signal based on the feedforward signal, the iterative learning signal, and the feedback signal as the heater power, output the control signal to the heater power supply, quantize the heater power of a sampling period to generate a quantization control signal having a quantized value for each of a plurality of quantization periods, the sampling period based on the measurement signal being maintained within a target range, and determine the quantization control signal as a final heater power.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a diagram illustrating a system according to some example embodiments of the present inventive concepts;

FIG. 2 is a diagram schematically illustrating a semiconductor processing system according to some example embodiments of the present inventive concepts;

FIG. 3 is a diagram schematically illustrating a semiconductor processing apparatus according to some example embodiments of the present inventive concepts;

FIG. 4 is a diagram schematically illustrating a semiconductor processing apparatus according to some example embodiments of the present inventive concepts;

FIG. 5 is a flowchart illustrating a process for determining final heater power according to some example embodiments of the present inventive concepts;

FIG. 6 is a block diagram schematically illustrating a temperature control system of a semiconductor processing apparatus according to some example embodiments of the present inventive concepts;

FIG. 7 is a block diagram schematically illustrating an iterative learning controller according to some example embodiments of the present inventive concepts;

FIG. 8A is a simulation diagram illustrating a control signal of a semiconductor processing apparatus according to some example embodiments of the present inventive concepts;

FIG. 8B is a simulation diagram illustrating a measurement signal of a semiconductor processing apparatus according to some example embodiments of the present inventive concepts;

FIGS. 9A and 9B are simulation diagrams illustrating measurement signals of a semiconductor processing apparatus according to some example embodiments of the present inventive concepts;

FIGS. 10A and 10B are diagrams illustrating process results of a semiconductor processing apparatus according to some example embodiments of the present inventive concepts; and

FIGS. 11 and 12 are diagrams illustrating a quantization control signal according to some example embodiments of the present inventive concept.

### DETAILED DESCRIPTION

Hereinafter, example embodiments of the present inventive concepts will be described with reference to the accompanying drawings.

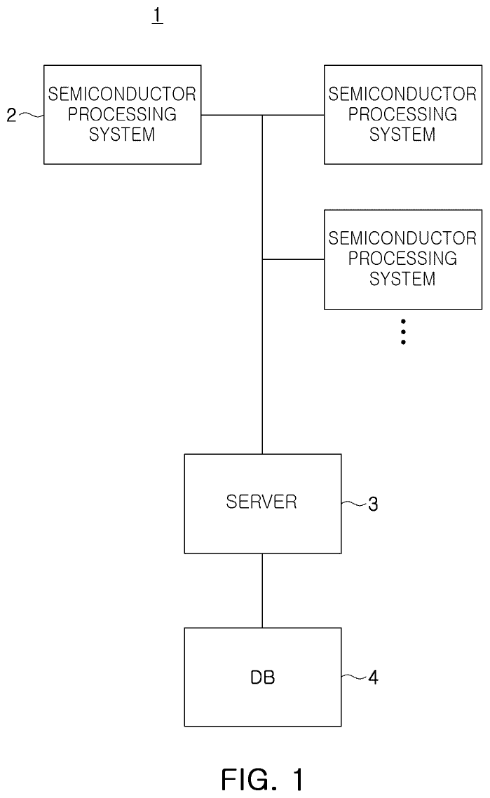

FIG. 1 is a diagram illustrating a system according to some example embodiments of the present inventive concept.

Referring to FIG. 1, the system 1 may include at least one semiconductor processing system 2, a server 3 and a database (DB) 4. In some example embodiments of the present inventive concepts, the semiconductor processing system 2 may include a wafer support, a heater power supply, and a processor. The wafer support may include a heater. A temperature of the wafer support may be controlled by heater power supplied to the heater by the heater power supply, and the processor may determine the heater power.

Since physical quantities used in a semiconductor process may affect process results, it may be important that the physical quantities remain stable during the semiconductor process. The physical quantities may include a radio frequency (RF) power, a chamber pressure, a gas flow rate, or the like. In some example embodiments, the temperature of the wafer support may take a significant amount of time to stabilize, and may be an important physical quantity affecting the results of processes, such as deposition or the like, in progress on the wafer. While a semiconductor process is in progress, it may be important to control the temperature of the wafer support to be (for example, quickly) stabilized and maintained.

While a semiconductor process is in progress, disturbance may be applied to the wafer support, and the temperature of the wafer support may fluctuate under the influence of the disturbance. For example, when a wafer is seated on the wafer support, the temperature of the wafer support may decrease. When gas flows into the semiconductor processing system 2, the temperature of the wafer support may decrease. Due to such temperature fluctuations in the wafer support, the temperature of the wafer seated on the wafer support may also fluctuate, thereby degrading process results and yield.

Before proceeding with the semiconductor process, the semiconductor processing system 2 may determine a control signal for controlling the physical quantity and control the physical quantity to remain stable. The system 1 may operate the semiconductor processing system 2 by reflecting the determined control signal. For example, the semiconductor processing system 2 may determine the heater power for controlling the temperature of the wafer support to be quickly stabilized and maintained.

In a typical semiconductor processing system, heater power may be determined by feedback controlling an error between a set temperature and a measured temperature of the wafer support. In other words, after a disturbance occurs and the temperature of the wafer support changes, the error may be reduced by changing the heater power.

The semiconductor processing system 2 according to some example embodiments of the present inventive concepts may determine the heater power by using iterative learning-based feedforward and feedback controls. The semiconductor processing system 2 may determine the heater power by iteratively analyzing and learning the error, and the error may be (for example, gradually or steadily) reduced so that the temperature of the wafer support may converge to the set temperature. That is, the semiconductor processing system 2 may (for example, gradually or steadily) and stably perform the semiconductor process.

According to some example embodiments of the present inventive concepts, a signal generated in the semiconductor processing system 2 may be transmitted to the server 3. At this time, the data may include a measurement signal obtained by measuring the temperature of the wafer support or the like. The server 3 may transmit the signal received from the semiconductor processing system 2 to the DB 4. The DB 4 may store the signal received from the server 3 and may transmit a signal requested by the server 3 to the server 3.

The system 1 of some example embodiments of the present inventive concepts may determine the heater power by using the iterative learning-based feedforward and feedback controls. Accordingly, while the semiconductor process is in progress, the temperature of the wafer support may be controlled to remain stable, thereby improving process results and enhancing yield.

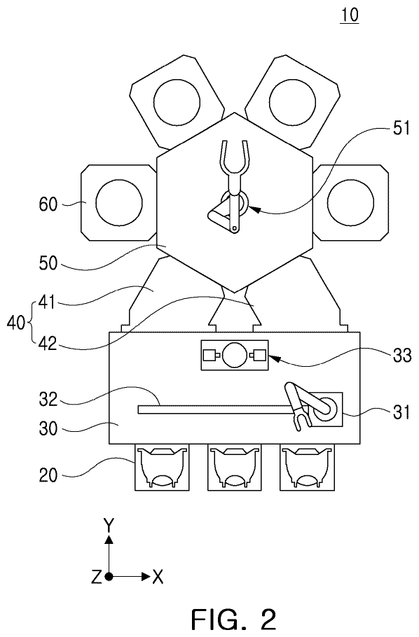

FIG. 2 is a diagram schematically illustrating a semiconductor processing system according to some example embodiments of the present inventive concept

Referring to FIG. 2, the semiconductor processing system 10 according to an example embodiment may include a wafer transfer apparatus 30, a load-lock chamber 40, a transfer chamber 50, a plurality of semiconductor processing apparatuses 60, and the like. For example, the wafer transfer apparatus 30 may receive wafers through a container such as a Front Opening Unified Pod (FOUP) 20 inside a line where the semiconductor processing system 10 is installed. The wafer transfer apparatus 30 may transfer the wafer received through the FOUP 20 to the load-lock chamber 40, or may receive wafers in which semiconductor processing has been completed in the plurality of semiconductor processing apparatuses 60, from the load-lock chamber 40, to be stored in the FOUP 20.

The wafer transfer apparatus 30 may include a wafer transfer robot 31 having an arm capable of grasping a wafer, a rail unit 32 for moving the wafer transfer robot 31 and an aligner 33 for aligning the wafer. Assuming an operation of transferring a wafer from the FOUP 20 to the load-lock chamber 40, the wafer transfer robot 31 may take out the wafer stored in the FOUP 20 and place the wafer on the aligner 33. The aligner 33 may rotate the wafer to align the wafer in a predetermined (or alternatively, desired or determined) direction. When wafer alignment is completed in the aligner 33, the wafer transfer robot 31 may take the wafer out of the aligner 33 and transfer the wafer to the load-lock chamber 40.

The load-lock chamber 40 is connected to the wafer transfer apparatus 30, and may include a loading chamber 41 where wafers brought into the semiconductor processing apparatuses 60 to proceed with the semiconductor process temporarily reside, and an unloading chamber 42 where wafers that are transported out of the semiconductor processing apparatuses 60 upon completion of the process temporarily reside. When a wafer aligned in the aligner 33 is brought into the loading chamber 41, the inside of the loading chamber 41 is depressurized to prevent or reduce external contaminants from entering.

The load-lock chamber 40 may be connected to the transfer chamber 50, and the plurality of semiconductor processing apparatuses 60 may be connected around the transfer chamber 50. A wafer transfer robot 51 may be disposed inside the transfer chamber 50 to transfer wafers between the load-lock chamber 40 and the plurality of semiconductor processing apparatuses 60. The wafer transfer robot 31 of the wafer transfer apparatus 30 may be referred to as a first wafer transfer robot, and the wafer transfer robot 51 of the transfer chamber 50 may be referred to as a second wafer transfer robot.

Each of the plurality of semiconductor processing apparatuses 60 may perform a semiconductor process on a wafer. For example, semiconductor processes performed by the plurality of semiconductor processing apparatuses 60 may include a deposition process, an etching process, an exposure process, an annealing process, a polishing process, an ion implantation process, and the like. In order to perform at least some of the above-mentioned semiconductor processes, plasma may be formed inside at least one of the plurality of semiconductor processing apparatus 60. Plasma may be formed on wafers, masks, display mother substrates, etc. which are subject to semiconductor processing.

Each of the plurality of semiconductor processing apparatus 60 according to some example embodiments of the present inventive concepts may include a wafer support, a heater power supply, and a processor. A wafer may be seated on the wafer support to perform a semiconductor process, and the wafer support may include a heater. A temperature of the wafer support may be controlled by heater power supplied to the heater by the heater power supply, and the processor may determine the heater power.

Before proceeding with the semiconductor process, the processor may determine the heater power to stably maintain the temperature of the wafer support. The processor of some example embodiments of the present inventive concepts may determine the heater power by using iterative learning-based feedforward and feedback controls. The processor may determine the heater power by iteratively analyzing and learning the error between a set temperature and a measured temperature, and the error may be (for example, gradually or steadily) reduced so that the temperature of the wafer support may converge to the set temperature.

The processor may operate the plurality of semiconductor processing apparatus 60 by reflecting the determined the heater power to proceed with the semiconductor process. While the semiconductor process is in progress, the temperature of the wafer support may be maintained within a predetermined target range of the set temperature. The predetermined target range of the set temperature as used herein may be alternatively or additionally be a selected target range or a determined target range, although the inventive concepts are not limited thereto.

Accordingly, while the semiconductor process is in progress, the temperature of the wafer support may be controlled to remain stable. In addition, performance imbalance between the plurality of semiconductor processing apparatuses 60 may be corrected, so that the plurality of semiconductor processing apparatuses 60 may produce consistent process results. Accordingly, the process results of the semiconductor processing system 10 according to some example embodiments of the present inventive concepts may be improved and the yield may be enhanced.

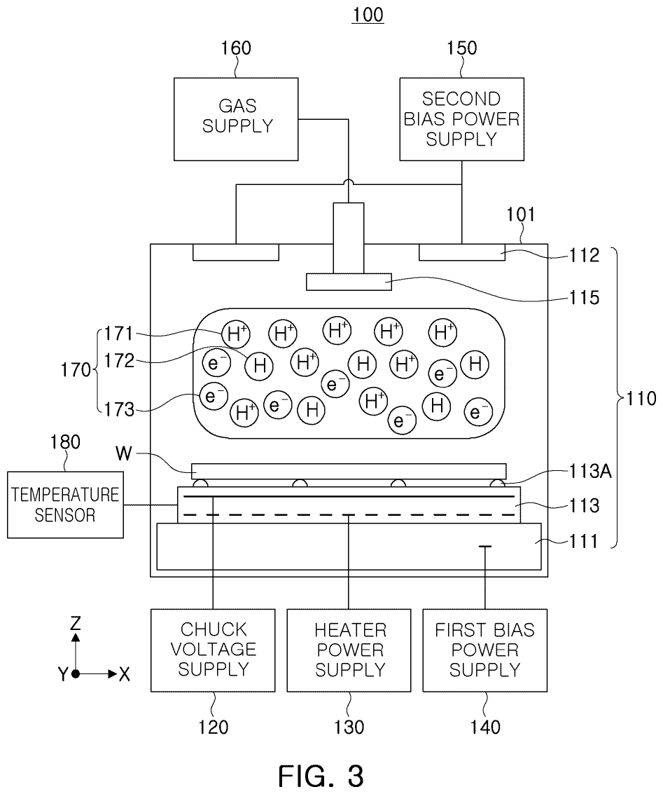

FIG. 3 is a diagram schematically illustrating a semiconductor processing apparatus according to some example embodiments of the present inventive concept

A semiconductor processing apparatus 100 according to some example embodiments of the present inventive concepts may be an apparatus that performs a semiconductor process using plasma. The semiconductor processing apparatus 100 may include a chamber 110, a chuck voltage supply 120, a heater power supply 130, a first bias power supply 140, a second bias power supply 150, a gas supply 160 and a temperature sensor 180.

The chamber 110 may include a housing 101, a first bias electrode 111, a second bias electrode 112, a wafer support 113 and a gas flow path 115. A semiconductor process object on which the semiconductor process will be performed may be seated on the wafer support 113. In some example embodiments shown in FIG. 3, the semiconductor process object is illustrated as a wafer W, but the semiconductor process object may be changed to a display mother substrate, a mask, and the like.

In some example embodiments, the wafer support 113 may correspond to an electrostatic chuck (ESC). A plurality of protrusions 113A having a protrusion shape may be formed on an upper surface of the wafer support 113. The wafer W is seated on the protrusion 113A, and thus a space may be formed between the upper surface of the wafer support 113 and the wafer W. For example, a space between the upper surface of the wafer support 113 and the wafer W may be filled with helium gas or the like for cooling the wafer W.

The wafer W may be fixed on the wafer support 113 by a Coulomb force generated from a chuck voltage supplied to the wafer support 113 by the chuck voltage supply 120. For example, the chuck voltage supply 120 may supply the chuck voltage to the wafer support 113 in the form of a constant voltage, and the chuck voltage may have a magnitude of hundreds to thousands of volts.

In another embodiment different from that of FIG. 3, the wafer W may be seated on a vacuum chuck or secured by a non-ESC based support (a non-chucking support). The non-ESC based support may secure the wafer W to the non-ESC based support unit by using mechanical clamping, vacuum based clamping or the like. However, the present inventive concepts may not be limited thereto.

A heater heating the semiconductor process object may be included inside the wafer support 113. The heater may be electrically connected to the heater power supply 130. By controlling heater power supplied to the heater by the heater power supply 130, the temperature of the wafer support 113 may be controlled.

The heater may correspond to a coil-shaped heating wire and may include at least one heating wire. However, the present inventive concepts may not be limited thereto. The heater may generate heat by resisting an applied voltage thereto, and the generated heat may be transferred to the wafer support 113. The temperature of the wafer support 113 may be determined by the generated and transferred heat.

Plasma gas may flow into the chamber 110 through the gas flow path 115 to proceed with the semiconductor process. The first bias power supply 130 may supply first bias power to the first bias electrode 111 located below the wafer support 113, and the second bias power supply 150 may supply second bias power to the second bias electrode 112 located above the wafer support 113. Each of the first bias power supply 140 and the second bias power supply 150 may include a radio frequency (RF) power source for supplying bias power.

A plasma 170 containing ions 171, radicals 172 and electrons 173 of the plasma gas may be generated in a space above the wafer W by the first bias power and the second bias power, and a reaction gas may be activated by the plasma 170 to increase reactivity. For example, in a case that the semiconductor processing apparatus 100 is an etching apparatus, the ions 171, the radicals 172 and the electrons 173 of the reaction gas may accelerated toward the wafer W by the first bias power supplied to the first bias electrode 111 by the first bias power supply 140. At least some of semiconductor substrates or layers included in the wafer W may be dry-etched by the ions 171, the radicals 172 and the electrons 173 of the reaction gas.

Before proceeding with the semiconductor process using the plasma 170, in some example embodiments of the present inventive concepts, final heater power supplied to the heater may be determined by using iterative learning-based feedforward and feedback controls. At this time, a signal representing the temperature of the wafer support 113 measured by the temperature sensor 180 may be used.

The semiconductor processing apparatus 100 according to some example embodiments of the present inventive concepts may be operated by reflecting the determined final heater power. The temperature of the wafer support 113 may be maintained within a predetermined target range, which may contribute to stably maintaining the temperature of the wafer W. Accordingly, process results on the wafer may be uniformly achieved, thereby enhancing reliability and yield of the semiconductor process.

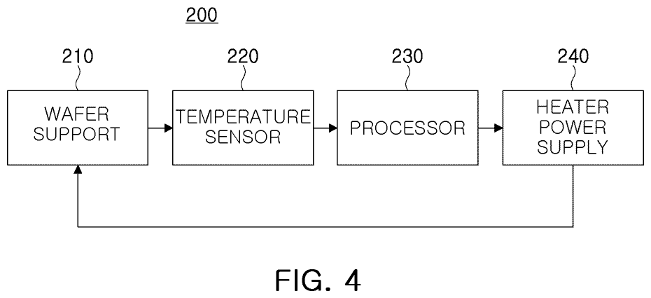

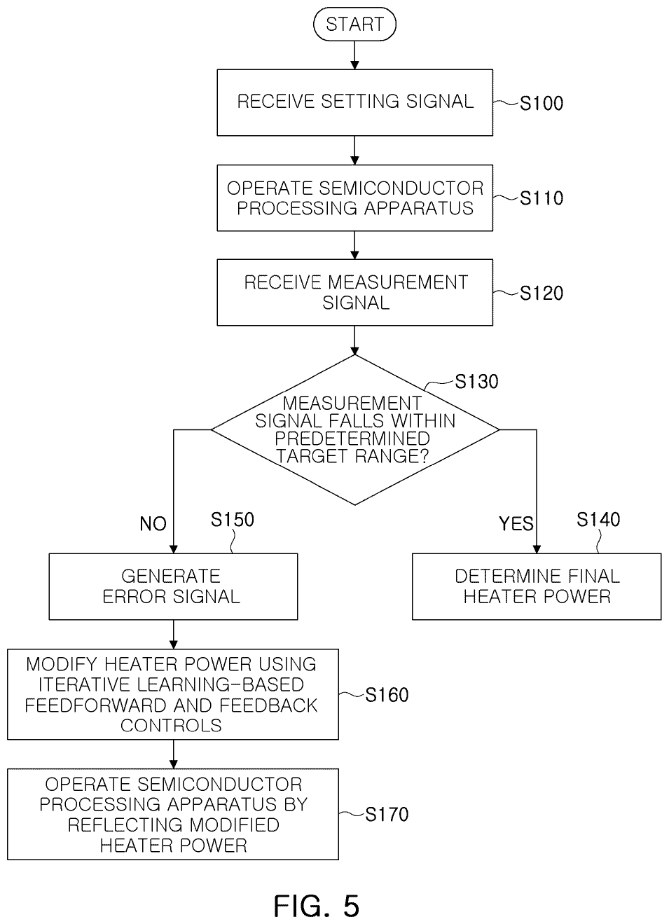

FIG. 4 is a diagram schematically illustrating a semiconductor processing apparatus according to some example embodiments of the present inventive concepts, and FIG. 5 is a flowchart illustrating a process for determining final heater power according to some example embodiments of the present inventive concept.

First, referring to FIG. 4, a semiconductor processing apparatus 200 may include a wafer support 210, a temperature sensor 220, a processor 230, and a heater power supply 240. Specific embodiments of the semiconductor processing apparatus may be similar to those described above in FIGS. 1 to 3. A wafer may be seated on the wafer support 210, and a semiconductor process may be performed. The wafer support 210 may include a heater. The heater power supply 240 may control a temperature of the wafer support 210 by supplying heater power to the heater.

The processor 230 may control the wafer support 210, the temperature sensor 220 and the heater power supply 240. The processor 230 may receive a setting signal indicating a set temperature of the wafer support 210. Before the semiconductor process begins, the processor 230 may use the setting signal to determine final heater power in order to maintain the temperature of the wafer support 210 within a predetermined target range.

The processor 230 may proceed with the semiconductor process by reflecting the determined final heater power. While the semiconductor process is in progress, the temperature of the wafer support 210 may be maintained within the predetermined target range. Hereinafter, the process for determining the final heater power is described in detail.

Referring to FIGS. 4 and 5, in operation S100, the processor 230 may receive the setting signal indicating the set temperature of the wafer support 210. For example, the setting signal may correspond to a signal indicating a constant temperature over time. However, the setting signal is not limited thereto, and may be a signal whose temperature changes with time. The processor 230 may determine the heater power using the setting signal.

In operation S110, the processor 230 may operate the semiconductor processing apparatus 200 by reflecting the heater power, and the semiconductor process for the wafer may proceed. The heater power may correspond to a signal representing power over time. The heater power may be divided on a basis of a sampling period. For example, the sampling period may correspond to a duration during which the semiconductor process for a single wafer is performed.

While the semiconductor process is in progress, the temperature sensor 220 may measure the temperature of the wafer support 210 and generate a measurement signal. The measurement signal may represent the temperature of the wafer support 210 over time. At this time, the temperature of the wafer support 210 may be a temperature reflecting disturbance. The disturbance may include at least one of wafer seating disturbance, RF power disturbance, chamber pressure disturbance and fluid flow disturbance. In operation S120, the temperature sensor 220 may output the measurement signal to the processor 230, and the processor 230 may receive the measurement signal. The measurement signal may be transmitted and stored in the DB 4 in FIG. 1.

In operation S130, the processor 230 may determine whether the measurement signal falls within the predetermined target range. The predetermined target range may be a predetermined (or alternatively, desired or determined) range of the set temperature. For example, the predetermined target range may correspond to a range within about or exactly 0.1° C. of the set temperature, a range within about or exactly 0.5° C. of the set temperature, or within about or exactly 1° C. of the set temperature, that is, between 0° C. and the temperature listed above.

If the measurement signal falls within the predetermined target range (YES in S130), in operation S140, the processor 230 may determine the final heater power. The final heater power may be the heater power applied to the semiconductor processing apparatus 200. Specifically, the heater power in the sampling period in which the measurement signal falls within a predetermined target range may be determined as the final heater power.

If the measurement signal fails to fall within the predetermined target range (NO in S130), the processor 230 may not determine the final heater power (S150 to S170). In operation 150, the processor 230 may generate an error signal based on the setting signal and the measurement signal. In an example, the error signal may be a difference between the setting signal and the measurement signal. The error signal may be divided on a basis of the same sampling period as the heater power.

In operation S160, the processor 230 may modify the heater power using the iterative learning-based feedforward and feedback controls. In operation S170, the processor 230 may operate the semiconductor processing apparatus 200 by reflecting the modified heater power.

Thereafter, the processor 230 may repeat the processes of receiving the measurement signal (S120) and determining whether the measurement signal falls within a predetermined target range (S130). By repeating the above processes, the processor 230 may determine the heater power of the sampling period in which the measurement signal falls within a predetermined target range as the final heater power.

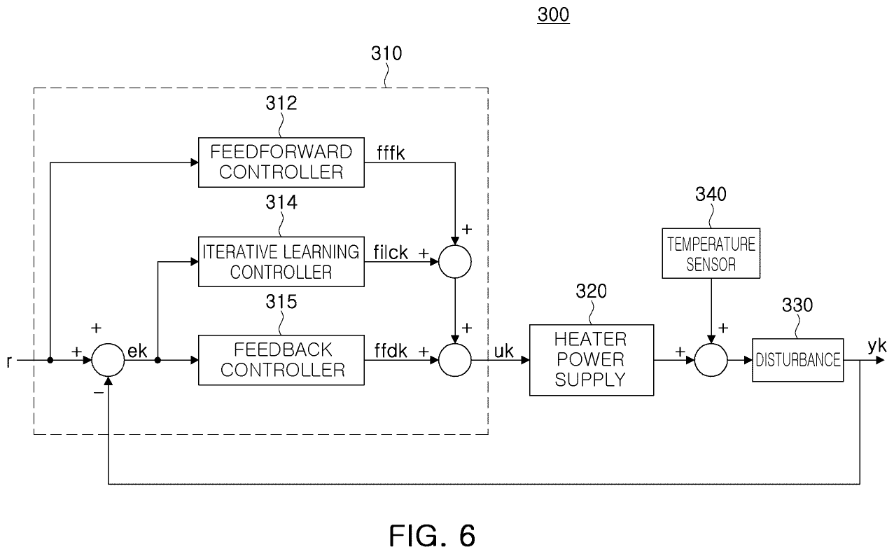

Hereinafter, the iterative learning-based feed-forward and feedback controls of the semiconductor processing apparatus 200 will be described in detail with reference to FIG. 6.

FIG. 6 is a block diagram schematically illustrating a temperature control system for a semiconductor processing apparatus according to some example embodiments of the present inventive concept.

First, referring to FIG. 6, a semiconductor processing apparatus 300 according to some example embodiments of the present inventive concepts may include a wafer support (not shown), a heater power supply 320, a temperature sensor 330 and a processor 310. The wafer support may include a heater, and the heater power supply 320 may supply heater power to the heater to control a temperature of the wafer support. The temperature sensor 330 may measure the temperature of the wafer support. The processor 310 may determine the heater power for maintaining the temperature of the wafer support within a predetermined target range. Specific embodiments of the semiconductor processing apparatus 300 may be similar to those described above in FIGS. 1 to 5.

In some example embodiments of the present inventive concepts, the processor 310 may receive a setting signal r. The setting signal r is a signal indicating a set temperature of the wafer support, and the set temperature may be a constant temperature in all sampling periods. In addition, the processor 310 may determine a control signal uk for the heater power to be supplied by the heater power supply 320 to the heater and output the control signal to the heater power supply 320.

In some example embodiments of the present inventive concepts, the temperature sensor 330 may measure the temperature of the wafer support on which both the control signal uk supplied to the heater power supply 320 and an influence of a disturbance 340 are reflected. The disturbance 340 may include wafer seating disturbance or the like. The disturbance 340 may correspond to a factor that changes the temperature of the wafer support with the heater power. The temperature sensor 330 may output a measurement signal yk obtained by measuring the temperature of the wafer support to the processor 310. The measurement signal yk may be transmitted to and stored in the DB 4 in FIG. 1.

At this time, k may mean a k^{th} sampling period. The measurement signal yk, the control signal uk may be signals for the k^{th} sampling period. In addition, k may represent a number of iterative learnings. Hereinafter, a specific embodiment of the processor 310 will be described.

The processor 310 may generate the control signal uk by performing the iterative learning-based feedforward and feedback controls of the setting signal r and the measurement signal yk. First, the processor 310 may generate an error signal ek, and the error signal ek may be a difference between the setting signal r and the measurement signal yk.

Referring to FIG. 6, the processor 310 may include a feedforward controller 312, an iterative learning controller (ILC) 314 and a feedback controller 316.

The feedforward controller 312 may receive the setting signal r and output a feedforward signal fffk. In other words, the feedforward controller 312 may control the setting signal r to generate the feedforward signal fffk. The feed forward signal fffk may be a signal indicating the heater power for the setting signal r. For example, the feed forward signal fffk may be a signal indicating the heater power for the set temperature and may represent constant power in all the sampling periods.

The iterative learning controller 314 may receive an error signal ek and output an iterative learning signal filck. In other words, the iterative learning controller 314 may control the error signal ek to generate an iterative learning signal filck. The iterative learning signal filck may be a signal that compensates for the feedforward signal fffk. For example, the iterative learning signal filck may represent an amount of change in the heater power indicated by the feed forward signal fffk.

The signal obtained by summing up the iterative learning signal filck and the feedforward signal fffk may be a result of the processor 310 performing the iterative learning-based feedforward control of the setting signal r and the measurement signal yk.

The feedback controller 315 may receive the error signal ek and output a feedback signal ffdk. In other words, the feedback controller 315 may control the error signal ek to generate the feedback signal ffdk. The feedback signal ffdk may be a signal indicating the heater power for the error signal ek. For example, the feedback signal ffdk may be a signal indicating the heater power for a difference between the set temperature and the measured temperature.

The processor 310 may sum up the feedforward signal fffk, the iterative learning signal filck and the feedback signal ffdk. The control signal uk may be a signal indicating the heater power of the k^{th} sampling period. The processor 310 may determine the control signal uk to the heater power supply 320. The processor 310 may output the heater power to the heater power supply 320. The heater power supply 320 may control the temperature of the wafer support by supplying the received heater power to the heater.

Referring also to FIG. 5, the semiconductor processing apparatus 300 may periodically repeat the above operations based on the sampling period. The processor 310 may determine the heater power of the sampling period in which the measurement signal yk falls within a predetermined target range as final heater power. The predetermined target range may be a predetermined (or alternatively, desired or determined) range of the set temperature.

For example, if the measurement signal yk of the k^{th} sampling period falls within a predetermined target range, the processor 310 may determine the control signal uk of the k^{th} sampling period as the final heater power. The processor 310 may operate the semiconductor processing apparatus 300 by reflecting the final heater power. Therefore, even if a disturbance which changes a temperature of the wafer support occurs while the semiconductor process is in progress, the temperature of the wafer support may be maintained within a predetermined (or alternatively, desired or determined) target range.

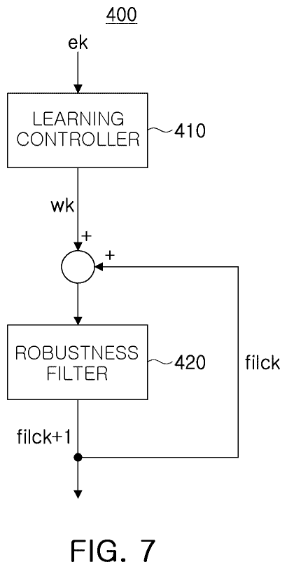

Hereinafter, the iterative learning controller 314 will be described in detail with reference to FIG. 7.

FIG. 7 is a block diagram schematically illustrating an iterative learning controller 400 according to some example embodiments of the present inventive concept.

Specific embodiments of a semiconductor processing apparatus may be similar to those previously described in FIGS. 1 to 6. The iterative learning controller 400 may analyze an error of a first sampling period and adjust a control signal so that a measurement signal is more stable in a second sampling period after the first sampling period. Specifically, the iterative learning controller 400 may analyze a temperature error of a wafer support in the first sampling period and adjust a heater power to reduce an error in the second sampling period. Hereinafter, the first sampling period may refer to a k^{th} sampling period, and the second sampling period may refer to a k+1^{th} sampling period.

The iterative learning controller 400 may include a learning controller 410 and a robustness filter 420.

The learning controller 410 may detect a change in a temperature of the wafer support (for example, based on a signal from a sensor, such as the temperature sensor 330) and control the heater power so that the temperature of the wafer support is stabilized at a set temperature. A learning gain may be stored in the learning controller 410. A rate at which heater power is controlled may be controlled by the learning gain. The higher the learning gain, the faster the learning controller 410 can respond to the change in the temperature of the wafer support.

The robustness filter 420 may control noise or uncertainty of a signal. For example, the robustness filter 420 may correspond to a low-pass filter (LPF). Accordingly, the robustness filter 420 may pass signals below a certain frequency and block signals above the certain frequency.

During the k^{th} sampling period, the iterative learning controller 400 may receive a k^{th} error signal ek and output a k^{th} iterative learning signal filck. At this time, the k^{th} error signal ek and the k^{th} iterative learning signal filck may be transmitted to and stored in the DB 4 in FIG. 1, but the present inventive concepts are not limited thereto.

During the k+1^{th} sampling period, the iterative learning controller 400 may use the stored k^{th} error signal ek and k^{th} iterative learning signal filck to generate a k+1^{th} iterative learning signal filck+1. At this time, the iterative learning controller 400 may receive a k+1^{th} error signal. The iterative learning signal filck+1 and the k+1^{th} error signal may be transmitted to and stored in the DB 4 in FIG. 1 and may be used to generate a k+2th iterative learning signal of a k+2th sampling period.

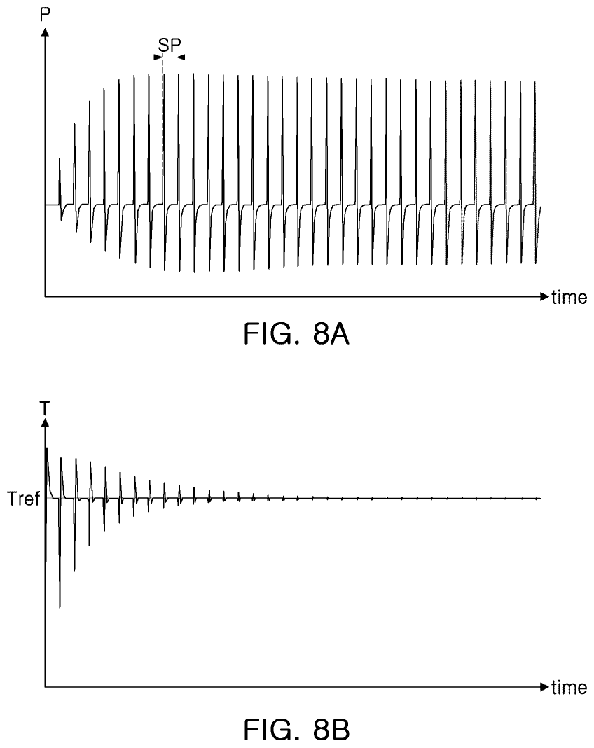

FIG. 8A is a simulation diagram illustrating a control signal of a semiconductor processing apparatus according to some example embodiments of the present inventive concept. FIG. 8B is a simulation diagram illustrating a measurement signal of a semiconductor processing apparatus according to some example embodiments of the present inventive concept.

The semiconductor processing apparatus may include a wafer support, a heater power supply, and a processor. Before a semiconductor process proceeds, the processor may use iterative learning-based feedforward and feedback controls to determine final heater power that maintains a temperature of the wafer support within a predetermined target range. The predetermined target range may be a predetermined (or alternatively, desired or determined) range of a set temperature Tref. Specific embodiments of the semiconductor processing apparatus may be similar to those previously described in FIGS. 1 to 7.

FIG. 8A may illustrate a control signal until the final heater power is determined. FIG. 8B may illustrate a measurement signal until the final heater power is determined. The control signal and the measurement signal may have a certain period, and the period may correspond to a sampling period SP.

The control signal illustrated in FIG. 8A may illustrate a heater power P over time. A unit of time may be second. The heater power P may correspond to a ratio to the maximum heater power that the heater power supply can supply to the heater, and a unit of the heater power P may be % (percentage).

The measurement signal illustrated in FIG. 8B may represent a temperature T of the wafer support over time. A unit of time may be second, and a unit of the temperature T of the wafer support may correspond to a Celsius temperature scale (° C.). By supplying the heater power P shown in FIG. 8.A to the heater with being influenced by disturbance, the temperature of the wafer support shown in FIG. 8B may be formed.

In an initial sampling period, a variation range of the heater power P may be minimal, and a variation range of the temperature T of the wafer support may be maximum. The variation range of the temperature T of the wafer support may be caused by the disturbance.

Thereafter, a variation range of an iterative learning signal constituting the heater power (P) may (for example, gradually or steadily) increase, and the variation range in a current sampling period may be greater than in the initial sampling period. Accordingly, the variation range of the temperature T of the wafer support may be smaller in a second sampling period after the current sampling period than in the first sampling period. In other words, the temperature T of the wafer support may (for example, gradually or steadily) converge to the set temperature TRef and stably maintained.

The processor may determine whether the temperature T of the wafer support in each sampling period is maintained within a predetermined (or alternatively, desired or determined) range of the set temperature Tref, and determine the heater power P of the corresponding sampling period as the final heater power.

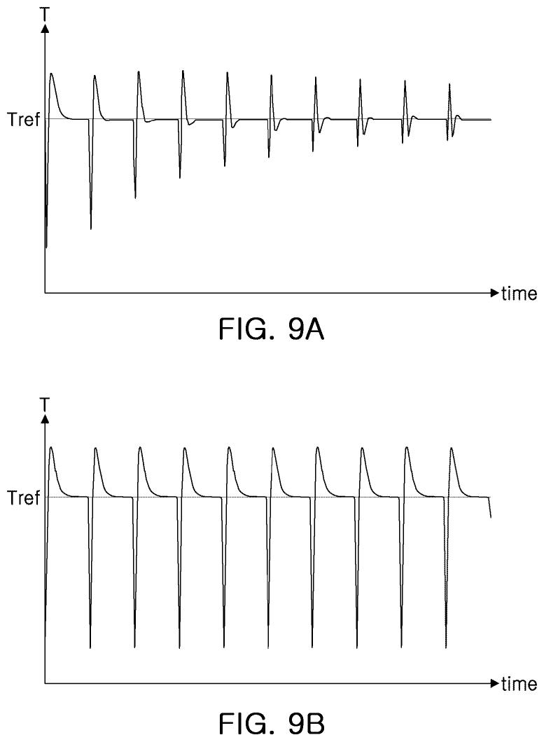

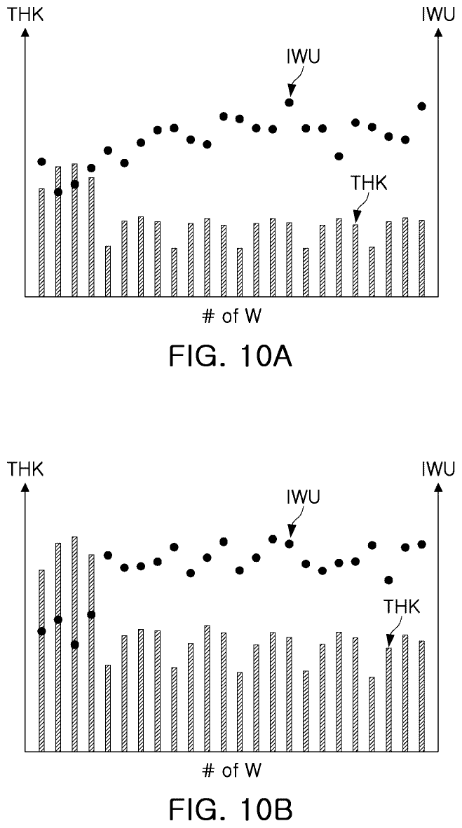

FIGS. 9A and 9B are simulation diagrams illustrating a measurement signal of a semiconductor processing apparatus according to some example embodiments of the present inventive concept. FIGS. 10A and 10B are diagrams illustrating process results of a semiconductor processing apparatus according to some example embodiments of the present inventive concept.

The semiconductor processing apparatus may determine heater power to maintain a measured temperature of a wafer support at a set temperature Tref. Specific embodiments of a semiconductor processing apparatus may be similar to those described above in FIGS. 1 to 8B.

Referring first to FIGS. 9A and 9B, FIG. 9A may illustrate a measurement signal of some example embodiments, and FIG. 9B may illustrate a measurement signal of a comparative example. The measurement signals may represent a temperature T of the wafer support over time. A unit of time may be second, and the temperature T of the wafer support may correspond to a Celsius temperature (° C.). The measurement signals may have a certain period, and the period may correspond to a sampling period SP.

Referring to FIGS. 10A and 10B, FIG. 10A may illustrate a process result for each wafer W in some example embodiments, and FIG. 10B may illustrate a process result for each wafer W of a comparative example. For example, a deposition process may be performed on the wafer W, and a thin film thickness THK and an in-wafer uniformity IWU of the wafer W may be calculated as the process result. By means of the process result, a wafer-to-wafer uniformity may be determined.

The thin film thickness THK may correspond to a thickness of a thin film at the same point of each wafer W, and a unit of the thin film thickness THK may be angstrom (Å). The in-wafer uniformity IWU may represent a degree of uniformity of the thin film measured at a plurality of points on each wafer W. The thin film uniformity IWU may be expressed as a percentage (%), and the lower the value, the higher the degree of uniformity.

A semiconductor processing apparatus of some example embodiments of the present inventive concepts may determine a heater power using iterative learning-based feedforward and feedback controls. A difference between a temperature T and a set temperature Tref of the wafer support of a previous sampling period may be repeatedly analyzed. A semiconductor processing apparatus of a comparative example different from embodiments of the present inventive concepts may determine the heater power using a feedback control. The difference between the temperature T and the set temperature Tref of the wafer support of the previous sampling period is not analyzed, and only the difference between the temperature T and the set temperature Tref of the wafer support of the current sampling period after the previous sampling period may be analyzed.

Referring to FIG. 9A, a variation range of the temperature T of the wafer support of some example embodiments may be (for example, gradually or steadily) reduced. Thereafter, the temperature T of the wafer support may converge to the set temperature Tref. Accordingly, while the semiconductor process is in progress, the temperature T of the wafer support may be controlled to be maintained within a predetermined (or alternatively, desired or determined) range of the set temperature Tref, so that the temperature of the wafer W may be stably maintained. The resulting process result may be illustrated in FIG. 10A.

Referring to FIG. 9B, a variation range of the temperature T of the wafer support of the comparative example may not significantly vary. For example, the variation range of the temperature T of the wafer support of the comparative example may be consistent with the variation range of the initial sampling period of the example. Accordingly, while the semiconductor process is in progress, the temperature of the wafer W may also significantly fluctuate. The resulting process result may be illustrated in FIG. 10B.

Comparing FIGS. 10A and 10B, the process result of some example embodiments may be improved over that of the comparative example. A deviation of the thin film thickness THK of some example embodiments may be less than a deviation of the thin film thickness THK of the comparative example. A deviation of the in-wafer uniformity IWU of some example embodiments may be less than a deviation of the in-wafer uniformity IWU of the comparative example, and an average of the in-wafer uniformity IWU of some example embodiments may be less than an average of the in-wafer uniformity IWU of the comparative example. That is, the semiconductor processing apparatus of some example embodiments may improve the process result and enhance yield by stably maintaining the temperature of the wafer support. For example, according to some example embodiments, there may be an increase and/or improvement in reliability, product produced, power consumption, and/or throughput based on the above methods. Therefore, the improved devices and methods overcome the deficiencies of the conventional devices and methods of semiconductor processing apparatuses while reducing resource consumption and improving the features noted above.

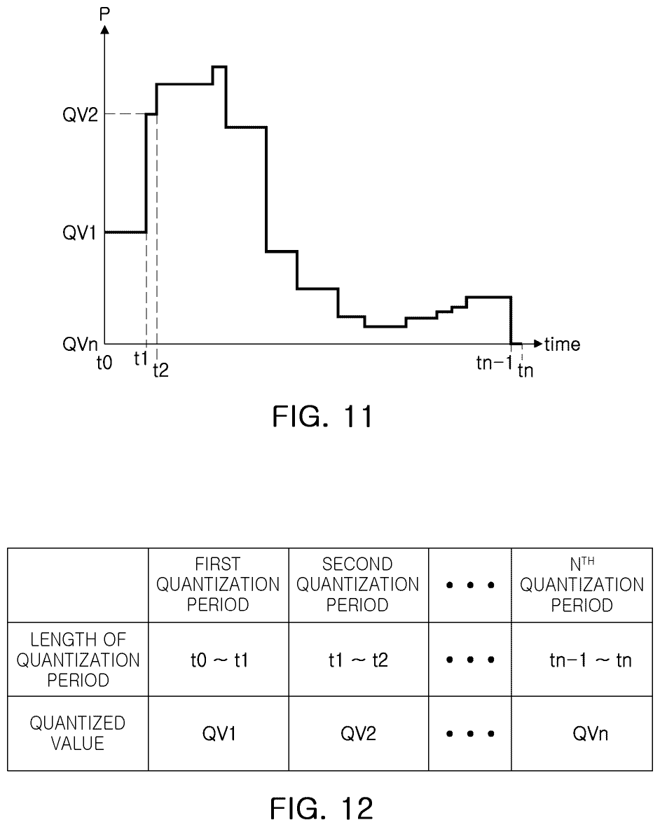

FIGS. 11 and 12 are diagrams illustrating a quantization control signals according to some example embodiments of the present inventive concept.

A semiconductor processing apparatus may include a wafer support, a heater power supply, and a processor. Before a semiconductor process proceeds, the processor may determine a heater power using iterative learning-based feedforward and feedback controls. The heater power may represent power over time. The heater power may have a certain period, and the period may correspond to a sampling period. Specific embodiments of the semiconductor processing apparatus may be similar to those described above with reference to FIGS. 1 to 10.

In some example embodiments of the present inventive concepts, the processor may generate a quantization control signal by quantizing the heater power in a sampling period in which a measurement signal obtained by measuring a temperature of the wafer support is maintained within a predetermined target range. The quantization control signal may be determined as final heater power.

The quantization control signal may have a quantized value QV for each of a plurality of quantization periods. Specifically, the quantization control signal may have a minimum sum of squared errors (SSEs) between the heater power and the quantized value. However, the present inventive concepts are not limited thereto.

First, FIG. 11 may illustrate the quantized value QV over time. The value may represent the heater power P. The heater power P may correspond to a ratio to the maximum heater power that the heater power supply may supply to the heater, and a unit of the heater power P may be %. A unit of time may be second, and the quantization control signal may have the quantized value for a time period from a 0^{th} time point t0 to a n^{th} time point tn. At this time, the time period from the 0^{th} time point t0 to the n^{th} time point tn may be a sampling period.

Referring to FIGS. 11 and 12, the quantization control signal may have first to n^{th} quantization values QV1 to QVn for each of the first to n^{th} quantization periods. A length of at least one of the first to n^{th} quantization periods may be different. In addition, at least one of the first to n^{th} quantization values QV1 to QVn may be different. However, the present inventive concepts are not limited thereto.

The first quantization period may have a length from the 0^{th} time point t0 to a first time point t1 and may have a first quantization value QV1. The second quantization period may have a length from the first time point t1 to a second time point t2 and may have a second quantization value QV2. A length of the second quantization period may be shorter than the first quantization period, and the second quantization value QV2 may be greater than the first quantization value QV1. However, the present inventive concepts are not limited thereto.

The n^{th} quantization section has a length from a n−1^{th} time point tn−1 to the n^{th} time point tn, and may have an n^{th} quantization value QVn. A length of the n^{th} quantization period may be the same as or different from at least one of the lengths of the first and second quantization periods. The n^{th} quantization value QVn may be the same as or different from at least one of the first and second quantization values QV1 and QV2. For example, the n^{th} quantization value QVn may be a minimum heater power P. However, the present inventive concepts are not limited thereto.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

According to some example embodiments of the present inventive concepts, a final heater power may be calculated in advance using iterative learning-based feedforward and feedback controls, and a temperature of a wafer support may be controlled to the final heater power while the semiconductor process is in progress, so that a temperature of the wafer support may be maintained within a predetermined (or alternatively, desired or determined) target range. Accordingly, the temperature control performance of the wafer support may be improved, a process result may be improved, and a yield may be enhanced.

While some example embodiments have been shown and described above, it will be apparent to those skilled in the art that modifications and variations could be made without departing from the scope of the present inventive concepts as defined by the appended claims.

What is claimed is:

1. A semiconductor processing apparatus, comprising
a wafer support including a heater;
a heater power supply configured to supply heater power to the heater to control a temperature of the wafer support; and
a processor configured to
receive a setting signal indicating a set temperature of the wafer support,
determine the heater power using the setting signal,
receive a measurement signal obtained by measuring the temperature of the wafer support,
generate an error signal based on the setting signal and the measurement signal,
generate a feedforward signal based on the setting signal,
generate an iterative learning signal based on the error signal,
generate a feedback signal based on the error signal,
determine a control signal based on the feedforward signal, the iterative learning signal, and the feedback signal as the heater power,
output the control signal to the heater power supply, and
determine the heater power in a sampling period as a final heater power, the sampling period based on the measurement signal being maintained within a target range.

2. The semiconductor processing apparatus of claim 1, wherein the setting signal is a signal representing a constant temperature over time.

3. The semiconductor processing apparatus of claim 1, wherein the measurement signal represents the temperature of the wafer support on which disturbance is reflected.

4. The semiconductor processing apparatus of claim 3, wherein the disturbance comprises at least one of wafer seating disturbance, RF power disturbance or fluid flow disturbance.

5. The semiconductor processing apparatus of claim 1, wherein the error signal represents a difference between the setting signal and the measurement signal.

6. The semiconductor processing apparatus of claim 1, wherein the processor is configured to generate the iterative learning signal of a second sampling period after a first sampling period, based on the error signal and the iterative learning signal of the first sampling period.

7. The semiconductor processing apparatus of claim 1, wherein the feedforward signal and the feedback signal represent the heater power over time.

8. The semiconductor processing apparatus of claim 1, wherein the iterative learning signal represents a compensation value for the heater power over time.

9. The semiconductor processing apparatus of claim 1, wherein a variation range of the iterative learning signal is greater in a second sampling period after a first sampling period than in the first sampling period.

10. The semiconductor processing apparatus of claim 9, wherein a variation range of the measurement signal is less in the second sampling period than in the first sampling period.

11. The semiconductor processing apparatus of claim 1, wherein the target range is a range of temperatures based on the set temperature.

12. The semiconductor processing apparatus of claim 11, wherein the target range has a difference of 0.5° C. or less of the set temperature.

13. A semiconductor processing apparatus, comprising
a wafer support including a heater;
a heater power supply configured to supply heater power to the heater to control a temperature of the wafer support, based on a semiconductor process being in progress; and
a processor comprising a feedforward controller, an iterative learning controller and a feedback controller, and the processor being configured to
receive a setting signal indicating a set temperature of the wafer support,
determine the heater power using the setting signal,
receive a measurement signal obtained by measuring the temperature of the wafer support on which disturbance is reflected,
generate an error signal based on a difference between the setting signal and the measurement signal,
transmit the setting signal to the feedforward controller,
control the feedforward controller to output a feedforward signal based on the setting signal,
transmit the error signal to the iterative learning controller,
control the iterative learning controller to output an iterative learning signal based on the error signal,
transmit the error signal to the feedback controller,
control the feedback controller to generate a feedback signal based on the error signal,
determine a control signal obtained based on the feedforward signal, the iterative learning signal, and the feedback signal as the heater power,
output the control signal to the heater power supply, and
determine the heater power in a sampling period as a final heater power, the sampling period being based on the measurement signal being maintained within a target range.

14. The semiconductor processing apparatus of claim 13, wherein the disturbance comprises at least one of wafer seating disturbance, RF power disturbance or fluid flow disturbance.

15. The semiconductor processing apparatus of claim 13, wherein the iterative learning controller is configured to generate the iterative learning signal of a second sampling period after a first sampling period, based on the error signal and the iterative learning signal of the first sampling period.

16. The semiconductor processing apparatus of claim 13, wherein
the iterative learning controller comprises at least one of a learning controller and a robustness filter,
the learning controller is configured to receive the error signal in a first sampling period and output a learning control signal,
the robustness filter is configured to receive the learning control signal and the iterative learning signal of the first sampling period and output the iterative learning signal of a second sampling period after the first sampling period.

17. The semiconductor processing apparatus of claim 16, wherein the robustness filter is a low-pass filter LPF.

18. A semiconductor processing apparatus, comprising
a wafer support including a heater;
a heater power supply configured to supply heater power to the heater to control a temperature of the wafer support, based on a semiconductor process being in progress; and
a processor configured to
receive a setting signal indicating a set temperature of the wafer support,
determine the heater power using the setting signal,
receive a measurement signal obtained by measuring the temperature of the wafer support on which disturbance is reflected,
generate an error signal based on a difference between the setting signal and the measurement signal,
generate a feedforward signal based on feedforward controlling the setting signal,
generate an iterative learning signal based on iterative learning controlling the error signal,
generate a feedback signal based on feedback controlling the error signal,
determine a control signal obtained based on the feedforward signal, the iterative learning signal, and the feedback signal as the heater power,
output the control signal to the heater power supply,
quantize the heater power of a sampling period to generate a quantization control signal having a quantized value for each of a plurality of quantization periods, the sampling period based on the measurement signal being maintained within a target range, and
determine the quantization control signal as a final heater power.

19. The semiconductor processing apparatus of claim 18, wherein at least one of the plurality of quantization periods has a different length.

20. The semiconductor processing apparatus of claim 18, wherein a quantized value for at least one of the plurality of quantization periods is different.
